(19) United States
(12) Patent Application Publication
(10) Pub. No.: US 2025/0179814 A1
(43) Pub. Date: Jun. 5, 2025

(54) LIFTING A FLOOR TILE OF A RAISED FLOOR

(71) Applicant: INTERNATIONAL BUSINESS MACHINES CORPORATION, ARMONK, NY (US)

(72) Inventors: JOHN S. WERNER, FISHKILL, NY (US); ARKADIY O. TSFASMAN, WAPPINGERS FALLS, NY (US); ROBERT WALSH, WALLKILL, NY (US); WOLF WOLBECK, WURTSBORO, NY (US); BRANDON GARY TYNDALE, POUGHKEEPSIE, NY (US)

(21) Appl. No.: 18/526,161

(22) Filed: Dec. 1, 2023

(51) Int. Cl. E04F 15/024; H05K 7/14

(52) U.S. Cl. CPC E04F 15/02464; H05K 7/1498

(57) ABSTRACT

Methods, systems, and products for lifting a floor tile of a raised floor includes: receiving, by a floor tile lift system and from a computing system proximate to a floor tile of a raised floor, an indication of a service to be performed, and raising the floor tile to a predetermined height based on the indication of the service to be performed.

### BACKGROUND

### Field of the Disclosure

The field of the disclosure is data processing, or, more specifically, methods, systems, and products for lifting a floor tile of a raised floor.

### Description of Related Art

Raised floors are used to provide a space between the base or floor of a building and the support floor or platform which objects or components may rest. In the example of a data center, raised floors may be a tiled floor which supports racks of computing systems, while allowing for cables or cooling equipment to be positioned under the raised floor. Performing maintenance or services on computing systems or other equipment that may be found in a data center often requires those performing the maintenance to have a space to rest tools or components. Equipment or tables or other movable workbenches used while performing such services must be stored and may take up valuable space on the raised floor or elsewhere in the data center.

### SUMMARY

Methods and systems for lifting a floor tile of a raised floor according to various embodiments are disclosed in this specification. In accordance with one aspect of the present disclosure, a method of lifting a floor tile of a raised floor may include receiving, by a floor tile lift system and from a computing system proximate to a floor tile of a raised floor, an indication of a service to be performed, and raising the floor tile to a predetermined height based on the indication of the service to be performed.

In accordance with another aspect of the present disclosure, lifting a floor tile of a raised floor may include a system including: a network module, and a computer processor configured to: receive, via the network module and from a computing system proximate to a floor tile of a raised floor, an indication of a service to be performed, and send instructions to a lifting mechanism to raise the floor tile to a predetermined height based on the indication of the service to be performed.

The foregoing and other objects, features and advantages of the disclosure will be apparent from the following more particular descriptions of exemplary embodiments of the disclosure as illustrated in the accompanying drawings wherein like reference numbers generally represent like parts of exemplary embodiments of the disclosure.

### BRIEF DESCRIPTION OF THE DRAWINGS

FIG. 1 shows an example line drawing of a system configured for lifting a floor tile of a raised floor in accordance with embodiments of the present disclosure.

FIG. 2 shows an example line drawing of a system that has lifted a floor tile of a raised floor in accordance with embodiments of the present disclosure.

FIG. 3 shows an example line drawing of a system configured for lifting a floor tile of a raised floor in accordance with embodiments of the present disclosure.

FIG. 4 is a block diagram of an example computing environment configured for lifting a floor tile of a raised floor according to some embodiments of the present disclosure.

FIG. 5 is a flowchart of an example method for lifting a floor tile of a raised floor according to some embodiments of the present disclosure.

### DETAILED DESCRIPTION

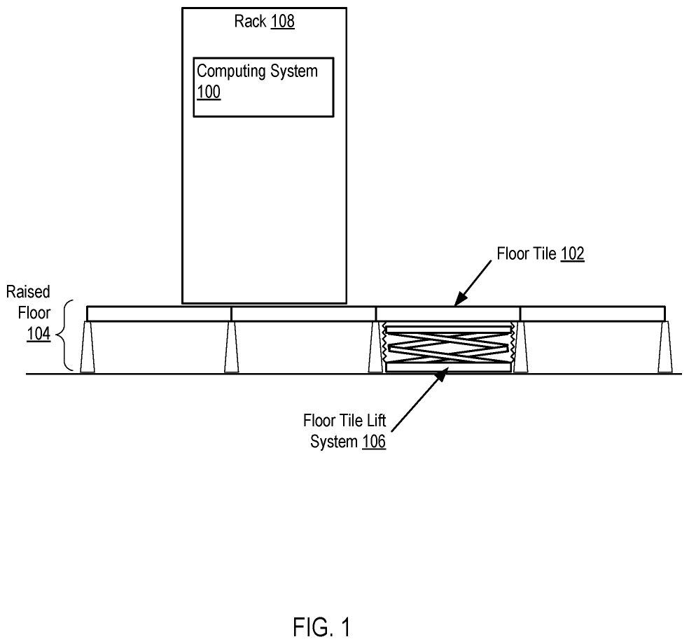

Exemplary methods, systems, and products for lifting a floor tile of a raised floor in accordance with the present disclosure are described with reference to the accompanying drawings, beginning with FIG. 1. FIG. 1 sets forth an example line drawing of a floor tile lift system implemented in a raised floor and configured for lifting a floor tile of a raised floor in accordance with embodiments of the present disclosure. The example of FIG. 1 includes a computing system 100 within a rack 108, a raised floor 104 having floor tiles (such as floor tile 102), and a floor tile lift system 106 positioned under floor tile 102.

The example floor tile lift system 106 in FIG. 1 is configured to raise a floor tile of a raised floor to a predetermined height based on communication with computing system 100. Computing system 100 may be proximate to the floor tile lift system 106 (as shown in FIG. 1) or may be positioned remotely from the floor tile lift system. In one embodiment, floor tile lift system 106 is configured to receive from computing system 100 an indication of a service to be performed and is also configured to raise the floor tile 102 to a predetermined height based on the received indication of the service to be performed. The service to be performed may include adding a new component to a rack (such as rack 108), adding a new or replacement component to computing system 100, performing maintenance on computing system 100 or another server or system included within rack 108 or some other rack, and the like. The indication may include the service to be performed, which may be determined based on a service schedule or some other method in which the computing system 100 has access to planned or scheduled services to be performed. In another embodiment, a user may input, into computing system 100, a service to be performed, which may in turn trigger sending the indication to the floor tile lift system 106.

The example floor tile lift system 106 of FIG. 1 may be commutatively coupled to the computing system 100 via a wired connection or a wireless connection. The floor tile lift system 106 may be powered via a wired connection to a power source or may be powered by batteries or some other local power supply within the floor tile lift system 106. The computing system 100 may be a server in a rack (as shown in FIG. 1) or may be some other type of computing system, such as a desktop, a smartphone or other smart device, a wearable computer, and the like.

The example raised floor 104 in FIG. 1 is configured to provide a space between the floor of the building and the floor on which equipment, such as computing systems or server racks, may rest on, where the space may be used for cabling (such as cables from the computing systems or racks), cooling components or infrastructure, and the like. In one embodiment, the raised floor 104 of FIG. 1 is a raised floor of a data center. Raised floor 104 includes one or more floor tiles (such as floor tile 102) and substructure configured to support the floor tiles.

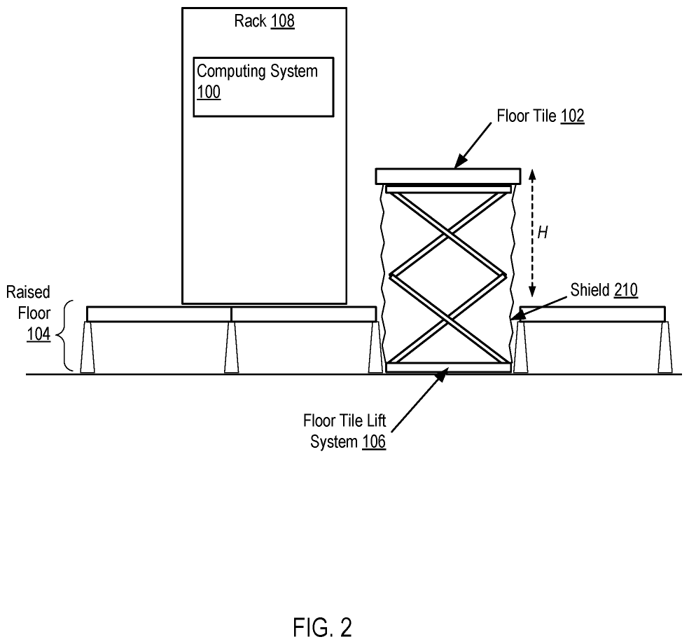

For further explanation, FIG. 2 sets forth another example line drawing of a floor tile lift system implemented in a raised floor and configured for lifting a floor tile of a raised floor in accordance with embodiments of the present disclosure. The example of FIG. 2 differs from FIG. 1 in that while FIG. 1 shows floor tile 102 in a lowered configuration, even or level with the raised floor, FIG. 2 shows floor tile 102 in a raised configuration, raised by the floor tile lift system 106.

The example of FIG. 2 shows the floor tile lift system 106 lifting floor tile 102 to a height of H. The height H that floor tile 102 is lifted may be predetermined based on the received indication. In one embodiment, the predetermined height H is based on the specific service that is to be performed. For example, if the service to be performed is adding a new component to the rack 108, the floor tile lift system 106 may raise the floor tile to a height H that is even with the position where the new component is being added within the rack. In another embodiment, the predetermined height H is based on a type of service included within the received indication. For example, if the type of service to be performed is for performing maintenance, the floor tile lift system 106 may lift the floor tile to a height H of a workbench or some other predetermined height useful for performing the service, whether previously set by user input or determined by computing system 100. Computing system 100 may determine a height for each type of service, or each specific service, to be performed. In another embodiment, a user may input a height for each type of service or even each specific service to be performed. The predetermined height H may be adjusted or customized after being initially set, based on user input, artificial intelligence, or some other method by computing system 100.

Example shield 210 in FIG. 2 is configured to block access to the space below the raised floor when the floor tile is in a raised position. For example, the shield may prevent objects or persons from falling into the space below the raised floor under the floor tile. The shield 210 of FIG. 2 is connected to the floor tile lift system. In another embodiment, the shield may be connected to the floor tile 102 or the raised floor. The shield 210 may be composed of a flexible material, such as a fabric or textile, and may expand in an accordion fashion as the floor tile lifts. In another embodiment, shield 210 may be composed of sliding plates or some other material.

The example of FIG. 2 shows the floor tile lift system 106 raising a single floor tile 102. In another embodiment, the floor tile lift system may be configured to lift two or more floor tiles simultaneously. In one embodiment, the floor tile lift system may lift two or more floor tiles simultaneously based on the indication or the service included in the received indication. For example, the service may be one which requires additional workspace for performing the service or the service may require additional surface area to lift a large component into the rack. In another embodiment, there may be multiple floor tile lift systems configured to lift multiple floor tiles of the raised floor simultaneously based on the indication received from the computing system. The multiple floor tiles that are lifted simultaneously may be side by side, touching, or in close proximity without touching. In one embodiment, the indication may be received by multiple floor tile lift systems, and the multiple lift systems receiving the indication may each raise a floor tile simultaneously for performing the service included in the indication. In another embodiment, a single floor tile lift system may receive an indication from the computing system and may communicate with other floor tile lift systems to work together to lift multiple floor tiles simultaneously. For example, floor tile lift system 106 may receive an indication from computing system 100 of a service to be performed where performing the service requires extensive surface area for tools, components, and the like. In such an example, the floor tile lift system may, based on the indication or service in the indication, communicate with another floor tile lift system proximate to the floor tile lift system 106 to lift another floor tile simultaneously with floor tile 102.

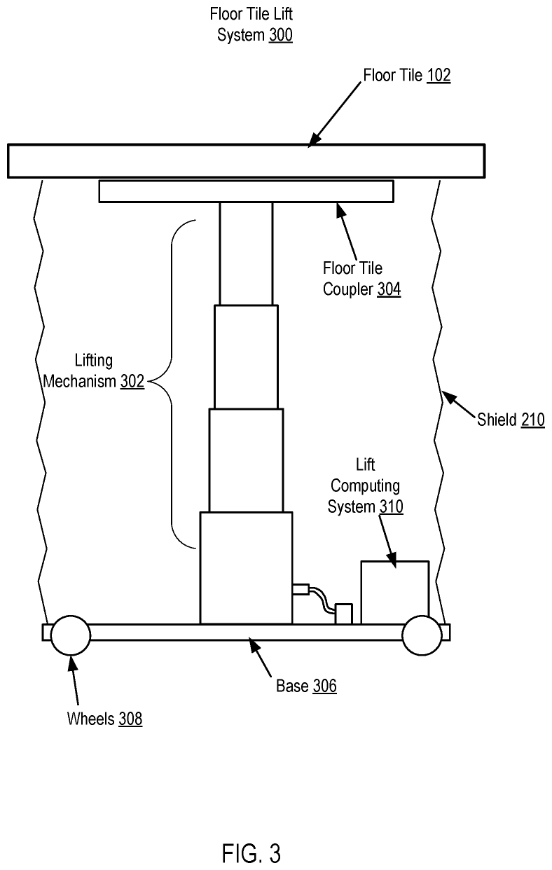

For further explanation, FIG. 3 sets forth a line diagram of an example floor tile lift system 300. The floor tile lift system 300 of FIG. 3 is another example of the floor tile lift system 106 of FIG. 1. The floor tile lift system 300 of FIG. 3 includes a lifting mechanism 302, a floor tile coupler 304, a shield 210, a base 306, wheels 308, and a lift computing system 310.

The lifting mechanism 302 of the floor tile lift system 300 may be any type of lifting mechanism, such as a scissor lift (as shown in FIG. 1), a pneumatic lift, a hydraulic lift (as shown here in FIG. 3), an electronic lift, and the like.

The floor tile coupler 304 may be any type of component used to couple the lifting mechanism to the floor tile for supporting the floor tile 102. In FIG. 3, the floor tile coupler 304 is a plate configured to support the floor tile. In other embodiments, the floor tile coupler may include one or more of a latch, a lock, hardware (such as screws or bolts), tabs, or any other component configured to connect to or support a floor tile. In one example one or more latches may couple to the different sides or edges of the floor tile when the floor tile is lifted. The floor tile coupler may be configured to adapt to multiple different floor tile sizes. The floor tile lift system 300 is configured to fully support the floor tile independent of whether the floor tile is raised or lowered. The floor tile, when supported by the floor tile lift system 300, is configured to support the same amount of weight as any other floor tile within the raised floor. Fully securing the floor tile to the floor tile lift system 300 when in a raised position prevents the floor tile from tipping, falling, or otherwise causing whatever the floor tile is supporting to become unstable. In another embodiment, the floor tile may be unsupported by the floor tile lift system 300 when in a lowered position, and instead fully supported by the raised floor and its substructure. In such an embodiment, the floor tile is supported by the floor tile lift system 300 whenever the floor tile is lifted off the raised floor.

The lifting mechanism 302 of FIG. 3 is coupled to lift computing system 310. Lift computing system 310 is configured to manage and control the floor tile lift system 300, including the lifting mechanism 302. The lift computing system 310 is configured to receive communication from other systems (such as from computing system 100) and send instructions to cause lifting mechanism 302 to raise floor tile 102.

The base 306 of the floor tile lift system 300 is coupled to an underside of the lifting mechanism and supports the lifting mechanism, the floor tile coupler, and the floor tile. Base 306 may rest directly on the ground or floor of the building or may include wheels 308, which may be extendable. Wheels 308 may be useful in transporting the floor tile lift system 300 when moving the floor tile lift system 300 from one floor tile to another.

In the embodiment of FIG. 3, the floor tile lift system is positioned beneath the floor tile with the floor tile resting on the floor tile lift system. In such an embodiment, the floor tile lift system may be movable from one floor tile to another. For example, the floor tile lift system is configured to be moved to another floor tile, such as by lifting the floor tile lift system out from under the raised floor, moving it to another position, and placing the floor tile lift system under another floor tile. In such an example, wheels 308 may be used to aid in moving the floor tile lift system 300. In another embodiment, the floor tile lift system 300 may be embedded within a floor tile of the raised floor as part of the floor tile. In yet another embodiment, the floor tile lift system may be moved remotely, by remote control, based on programming, without human interaction, automatically based on service schedules, by a robot, by user input (via wired connection or remote connection), and the like. The floor tile lift system may be remotely controlled to move between floor tiles while staying beneath the raised floor. In such an example, the floor tile lift system is wirelessly connected to computing system 100.

The floor tile lift system 300 is configured to both raise and lower floor tile 102. Lowering the floor tile may be carried out based on user input directly into the floor tile lift system, such as via a switch or button included on the floor tile lift system (not shown in FIG. 3). Alternatively, lowering the floor tile may be carried out based on user input to a computing system separate from the floor tile lift system (such as computing system 100). Lowering the floor tile may also be carried out automatically, via a computing system like computing system 100. For example, the indication received may include an indication of how long to keep the floor tile raised and when to lower the floor tile. Alternatively, the floor tile lift system may be configured to lower the floor tile after a predetermined period of time or based on a schedule or time of day. Lowering the floor tile may be carried out after the service is performed.

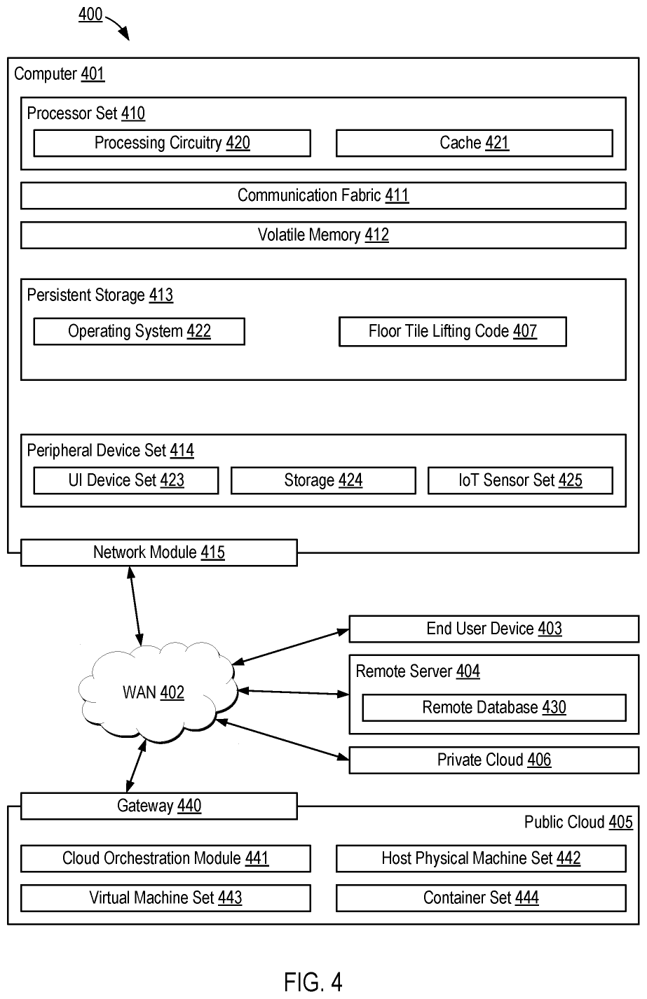

For further explanation, FIG. 4 sets forth a block diagram of computing environment 400 configured for lifting a floor tile of a raised floor in accordance with embodiments of the present disclosure. Computing environment 400 contains an example of an environment for the execution of at least some of the computer code involved in performing the inventive methods, such as floor tile lifting code 407. In addition to floor tile lifting code 407, computing environment 400 includes, for example, computer 401, wide area network (WAN) 402, end user device (EUD) 403, remote server 404, public cloud 405, and private cloud 406. In this example embodiment, computer 401 is the lift computing system of FIG. 3, and includes processor set 410 (including processing circuitry 420 and cache 421), communication fabric 411, volatile memory 412, persistent storage 413 (including operating system 422 and floor tile lifting code 407, as identified above), peripheral device set 414 (including user interface (UI) device set 423, storage 424, and Internet of Things (IoT) sensor set 425), and network module 415. Remote server 404 includes remote database 430. Public cloud 405 includes gateway 440, cloud orchestration module 441, host physical machine set 442, virtual machine set 443, and container set 444.

Computer 401 may take the form of a desktop computer, laptop computer, tablet computer, smart phone, wearable computer, smart watch, mainframe computer, quantum computer or any other form of computer or mobile device now known or to be developed in the future that is capable of running a program, accessing a network or querying a database, such as remote database 430. As is well understood in the art of computer technology, and depending upon the technology, performance of a computer-implemented method may be distributed among multiple computers and/or between multiple locations. On the other hand, in this presentation of computing environment 400, detailed discussion is focused on a single computer, specifically computer 401, to keep the presentation as simple as possible. Computer 401 may be located in a cloud, even though it is not shown in a cloud in FIG. 4. On the other hand, computer 401 is not required to be in a cloud except to any extent as may be affirmatively indicated.

Processor set 410 includes one, or more, computer processors of any type now known or to be developed in the future. Processing circuitry 420 may be distributed over multiple packages, for example, multiple, coordinated integrated circuit chips. Processing circuitry 420 may implement multiple processor threads and/or multiple processor cores. Cache 421 is memory that is located in the processor chip package(s) and is typically used for data or code that should be available for rapid access by the threads or cores running on processor set 410. Cache memories are typically organized into multiple levels depending upon relative proximity to the processing circuitry. Alternatively, some, or all, of the cache for the processor set may be located “off chip.” In some computing environments, processor set 410 may be designed for working with qubits and performing quantum computing.

Computer readable program instructions are typically loaded onto computer 401 to cause a series of operational steps to be performed by processor set 410 of computer 401 and thereby effect a computer-implemented method, such that the instructions thus executed will instantiate the methods specified in flowcharts and/or narrative descriptions of computer-implemented methods included in this document (collectively referred to as “the inventive methods”). These computer readable program instructions are stored in various types of computer readable storage media, such as cache 421 and the other storage media discussed below. The program instructions, and associated data, are accessed by processor set 410 to control and direct performance of the inventive methods. In computing environment 400, at least some of the instructions for performing the inventive methods may be stored in floor tile lifting code 407 in persistent storage 413.

Communication fabric 411 is the signal conduction path that allows the various components of computer 401 to communicate with each other. Typically, this fabric is made of switches and electrically conductive paths, such as the switches and electrically conductive paths that make up buses, bridges, physical input/output ports and the like. Other types of signal communication paths may be used, such as fiber optic communication paths and/or wireless communication paths.

Volatile memory 412 is any type of volatile memory now known or to be developed in the future. Examples include dynamic type random access memory (RAM) or static type RAM. Typically, volatile memory 412 is characterized by random access, but this is not required unless affirmatively indicated. In computer 401, the volatile memory 412 is located in a single package and is internal to computer 401, but, alternatively or additionally, the volatile memory may be distributed over multiple packages and/or located externally with respect to computer 401.

Persistent storage 413 is any form of non-volatile storage for computers that is now known or to be developed in the future. The non-volatility of this storage means that the stored data is maintained regardless of whether power is being supplied to computer 401 and/or directly to persistent storage 413. Persistent storage 413 may be a read only memory (ROM), but typically at least a portion of the persistent storage allows writing of data, deletion of data and re-writing of data. Some familiar forms of persistent storage include magnetic disks and solid state storage devices. Operating system 422 may take several forms, such as various known proprietary operating systems or open source Portable Operating System Interface-type operating systems that employ a kernel. The code included in floor tile lifting code 407 typically includes at least some of the computer code involved in performing the inventive methods.

Peripheral device set 414 includes the set of peripheral devices of computer 401. Data communication connections between the peripheral devices and the other components of computer 401 may be implemented in various ways, such as Bluetooth connections, Near-Field Communication (NFC) connections, connections made by cables (such as universal serial bus (USB) type cables), insertion-type connections (for example, secure digital (SD) card), connections made through local area communication networks and even connections made through wide area networks such as the internet. In various embodiments, UI device set 423 may include components such as a display screen, speaker, microphone, wearable devices (such as goggles and smart watches), keyboard, mouse, printer, touchpad, game controllers, and haptic devices. Storage 424 is external storage, such as an external hard drive, or insertable storage, such as an SD card. Storage 424 may be persistent and/or volatile. In some embodiments, storage 424 may take the form of a quantum computing storage device for storing data in the form of qubits. In embodiments where computer 401 is required to have a large amount of storage (for example, where computer 401 locally stores and manages a large database) then this storage may be provided by peripheral storage devices designed for storing very large amounts of data, such as a storage area network (SAN) that is shared by multiple, geographically distributed computers. IoT sensor set 425 is made up of sensors that can be used in Internet of Things applications. For example, one sensor may be a thermometer and another sensor may be a motion detector.

Network module 415 is the collection of computer software, hardware, and firmware that allows computer 401 to communicate with other computers through WAN 402. Network module 415 may include hardware, such as modems or Wi-Fi signal transceivers, software for packetizing and/or de-packetizing data for communication network transmission, and/or web browser software for communicating data over the internet. In some embodiments, network control functions and network forwarding functions of network module 415 are performed on the same physical hardware device. In other embodiments (for example, embodiments that utilize software-defined networking (SDN)), the control functions and the forwarding functions of network module 415 are performed on physically separate devices, such that the control functions manage several different network hardware devices. Computer readable program instructions for performing the inventive methods can typically be downloaded to computer 401 from an external computer or external storage device through a network adapter card or network interface included in network module 415. Network module 415 may be configured to communicate with other systems, such as computing system 100, for receiving indications and the like, or to communicate with other floor tile lift systems, such as when working together with other floor tile lift systems to lift multiple floor tiles simultaneously.

WAN 402 is any wide area network (for example, the internet) capable of communicating computer data over non-local distances by any technology for communicating computer data, now known or to be developed in the future. In some embodiments, the WAN 402 may be replaced and/or supplemented by local area networks (LANs) designed to communicate data between devices located in a local area, such as a Wi-Fi network. The WAN and/or LANs typically include computer hardware such as copper transmission cables, optical transmission fibers, wireless transmission, routers, firewalls, switches, gateway computers and edge servers.

End User Device (EUD) 403 is any computer system that is used and controlled by an end user (for example, a customer of an enterprise that operates computer 401), and may take any of the forms discussed above in connection with computer 401. EUD 403 typically receives helpful and useful data from the operations of computer 401. For example, in a hypothetical case where computer 401 is designed to provide a recommendation to an end user, this recommendation would typically be communicated from network module 415 of computer 401 through WAN 402 to EUD 403. In this way, EUD 403 can display, or otherwise present, the recommendation to an end user. In some embodiments, EUD 403 may be a client device, such as thin client, heavy client, mainframe computer, desktop computer and so on.

Remote server 404 is any computer system that serves at least some data and/or functionality to computer 401. Remote server 404 may be controlled and used by the same entity that operates computer 401. Remote server 404 represents the machine(s) that collect and store helpful and useful data for use by other computers, such as computer 401. For example, in a hypothetical case where computer 401 is designed and programmed to provide a recommendation based on historical data, then this historical data may be provided to computer 401 from remote database 430 of remote server 404.

Public cloud 405 is any computer system available for use by multiple entities that provides on-demand availability of computer system resources and/or other computer capabilities, especially data storage (cloud storage) and computing power, without direct active management by the user. Cloud computing typically leverages sharing of resources to achieve coherence and economies of scale. The direct and active management of the computing resources of public cloud 405 is performed by the computer hardware and/or software of cloud orchestration module 441. The computing resources provided by public cloud 405 are typically implemented by virtual computing environments that run on various computers making up the computers of host physical machine set 442, which is the universe of physical computers in and/or available to public cloud 405. The virtual computing environments (VCEs) typically take the form of virtual machines from virtual machine set 443 and/or containers from container set 444. It is understood that these VCEs may be stored as images and may be transferred among and between the various physical machine hosts, either as images or after instantiation of the VCE. Cloud orchestration module 441 manages the transfer and storage of images, deploys new instantiations of VCEs and manages active instantiations of VCE deployments. Gateway 440 is the collection of computer software, hardware, and firmware that allows public cloud 405 to communicate through WAN 402.

Some further explanation of virtualized computing environments (VCEs) will now be provided. VCEs can be stored as “images.” A new active instance of the VCE can be instantiated from the image. Two familiar types of VCEs are virtual machines and containers. A container is a VCE that uses operating-system-level virtualization. This refers to an operating system feature in which the kernel allows the existence of multiple isolated user-space instances, called containers. These isolated user-space instances typically behave as real computers from the point of view of programs running in them. A computer program running on an ordinary operating system can utilize all resources of that computer, such as connected devices, files and folders, network shares, CPU power, and quantifiable hardware capabilities. However, programs running inside a container can only use the contents of the container and devices assigned to the container, a feature which is known as containerization.

Private cloud 406 is similar to public cloud 405, except that the computing resources are only available for use by a single enterprise. While private cloud 406 is depicted as being in communication with WAN 402, in other embodiments a private cloud may be disconnected from the internet entirely and only accessible through a local/private network. A hybrid cloud is a composition of multiple clouds of different types (for example, private, community or public cloud types), often respectively implemented by different vendors. Each of the multiple clouds remains a separate and discrete entity, but the larger hybrid cloud architecture is bound together by standardized or proprietary technology that enables orchestration, management, and/or data/application portability between the multiple constituent clouds. In this embodiment, public cloud 405 and private cloud 406 are both part of a larger hybrid cloud.

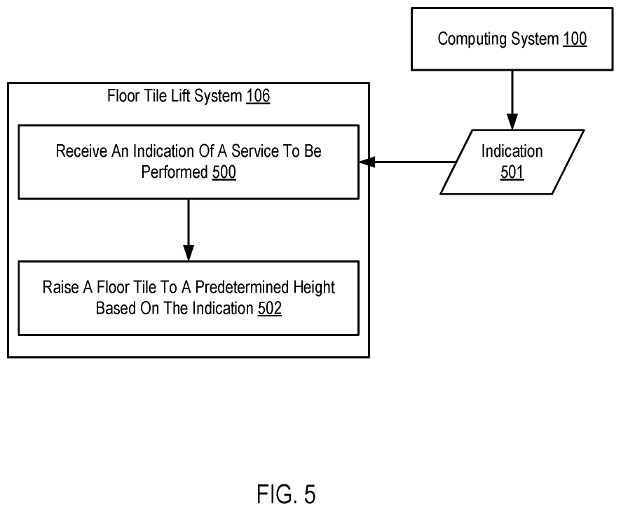

For further explanation, FIG. 5 sets forth a flow chart illustrating an exemplary method of lifting a floor tile of a raised floor according to embodiments of the present disclosure. The method of FIG. 5 includes receiving 500 an indication of a service to be performed. Receiving 500 an indication of a service to be performed may be carried out by the floor tile lift system 106 receiving the indication 501 from the computing system 100, where the indication specifies a service that is to be performed. The indication 501 may be received wirelessly over a network or may be received via a wired communication connection between the floor tile lift system and the computing system 100. The indication may include one or more of an indication of the service to be performed, a type of service, a time when the service is scheduled to be performed, a window for how long to raise the floor tile, an indication of the height to raise the floor tile, which floor tile to raise, whether or not to communicate with other floor tile lift systems or raise additional floor tiles, and the like. The service may be any service or maintenance task to be performed on a computing system or rack or other data center equipment.

The method of FIG. 5 also includes raising 502 a floor tile to a predetermined height based on the indication. Raising 502 the floor tile may be carried out automatically by the floor tile lift system 106 lifting the floor tile to a predetermined height based on the information included within the received indication 501. In some embodiments, the predetermined height may be based on a type of the service to be performed that is indicated within the indication 501. For example, when the service to be performed is adding a new component to a rack (such as rack 108 of FIG. 1 that includes computing system 100), the predetermined height that the floor tile is raised to may be the height at which the new component will be added to the rack.

In view of the explanations set forth above, readers will recognize that the benefits of lifting a floor tile of a raised floor according to embodiments of the present disclosure include:
Adding functionality to raised floors by allowing for using a floor tile as a workplace, table, or lift for moving parts, tools, or components when performing maintenance or services.
Increasing service efficiency by allowing for a workspace near to where the service is being performed, reducing the requirement for equipment that may take up space on top of the raised floor.

Various aspects of the present disclosure are described by narrative text, flowcharts, block diagrams of computer systems and/or block diagrams of the machine logic included in computer program product (CPP) embodiments. With respect to any flowcharts, depending upon the technology involved, the operations can be performed in a different order than what is shown in a given flowchart. For example, again depending upon the technology involved, two operations shown in successive flowchart blocks may be performed in reverse order, as a single integrated step, concurrently, or in a manner at least partially overlapping in time.

A computer program product embodiment (“CPP embodiment” or “CPP”) is a term used in the present disclosure to describe any set of one, or more, storage media (also called “mediums”) collectively included in a set of one, or more, storage devices that collectively include machine readable code corresponding to instructions and/or data for performing computer operations specified in a given CPP claim. A “storage device” is any tangible device that can retain and store instructions for use by a computer processor. Without limitation, the computer readable storage medium may be an electronic storage medium, a magnetic storage medium, an optical storage medium, an electromagnetic storage medium, a semiconductor storage medium, a mechanical storage medium, or any suitable combination of the foregoing. Some known types of storage devices that include these mediums include: diskette, hard disk, random access memory (RAM), read-only memory (ROM), erasable programmable read-only memory (EPROM or Flash memory), static random access memory (SRAM), compact disc read-only memory (CD-ROM), digital versatile disk (DVD), memory stick, floppy disk, mechanically encoded device (such as punch cards or pits/lands formed in a major surface of a disc) or any suitable combination of the foregoing. A computer readable storage medium, as that term is used in the present disclosure, is not to be construed as storage in the form of transitory signals per se, such as radio waves or other freely propagating electromagnetic waves, electromagnetic waves propagating through a waveguide, light pulses passing through a fiber optic cable, electrical signals communicated through a wire, and/or other transmission media. As will be understood by those of skill in the art, data is typically moved at some occasional points in time during normal operations of a storage device, such as during access, de-fragmentation or garbage collection, but this does not render the storage device as transitory because the data is not transitory while it is stored.

It will be understood from the foregoing description that modifications and changes may be made in various embodiments of the present disclosure without departing from its true spirit. The descriptions in this specification are for purposes of illustration only and are not to be construed in a limiting sense. The scope of the present disclosure is limited only by the language of the following claims.

What is claimed is:

1. A floor tile lift system comprising:
a floor tile coupler configured to couple to an underside of a floor tile included in a raised floor;
a lifting mechanism coupled to the floor tile coupler; and
a computer processor configured to:
receive, from a computing system proximate to the floor tile, an indication of a service to be performed; and
raise, via the floor tile coupler and the lifting mechanism, the floor tile to a predetermined height based on the indication of the service to be performed.

2. The floor tile lift system of claim 1, wherein the predetermined height is based on a type of the service to be performed.

3. The floor tile lift system of claim 1, wherein the floor tile lift system communicates with the computing system via a wired connection.

4. The floor tile lift system of claim 1, wherein the floor tile lift system communicates with the computing system via a wireless connection.

5. The floor tile lift system of claim 1, wherein the floor tile lift system is movable to one or more other floor tiles included within the raised floor.

6. The floor tile lift system of claim 1, wherein the service to be performed includes adding a component to a rack.

7. The floor tile lift system of claim 1, wherein the lifting mechanism comprises a pneumatic lift.

8. The floor tile lift system of claim 1, wherein the computing system comprises a server in a rack.

9. The floor tile lift system of claim 1, wherein the raised floor is included within a data center.

10. The floor tile lift system of claim 1, further comprising a shield configured to block access to an area under the raised floor when the floor tile is in a raised position.

11. The floor tile lift system of claim 1, further comprising multiple wheels mounted to a base of the floor tile lift system.

12. An apparatus comprising:
a network module; and
a computer processor configured to:
receive, via the network module and from a computing system proximate to a floor tile of a raised floor, an indication of a service to be performed; and
send instructions to a lifting mechanism to raise the floor tile to a predetermined height based on the indication of the service to be performed.

13. The apparatus of claim 12, wherein the predetermined height is based on a type of the service to be performed.

14. The apparatus of claim 12, wherein the service to be performed includes performing maintenance on the computing system.

15. The apparatus of claim 12, wherein the service to be performed includes adding a component to a rack.

16. The apparatus of claim 12, wherein the computer processor communicates with the computing system via a wireless connection.

17. A method of lifting a floor tile of a raised floor, the method comprising:
receiving, by a floor tile lift system and from a computing system proximate to a floor tile of a raised floor, an indication of a service to be performed; and
raising the floor tile to a predetermined height based on the indication of the service to be performed.

18. The method of claim 17, wherein the predetermined height is based on a type of the service to be performed.

19. The method of claim 17, wherein the floor tile lift system communicates with the computing system via a wireless connection.

20. The method of claim 17, wherein the service to be performed includes performing maintenance on the computing system.
